(19) United States
(12) Patent Application Publication
(10) Pub. No.: US 2026/0136879 A1
(43) Pub. Date: May 14, 2026

(54) Methods and Apparatus for Processing a Substrate Using Ellipsometry

(71) Applicants: Applied Meterials, Inc., Santa Clara, CA (US); NATIONAL UNIVERSITY OF SINGAPORE, Singapore (SG)

(72) Inventors: Prayudi LIANTO, Singapore (SG); Raymond HUNG, Palo Alto, CA (US); Andrivo RUSYDI, Singapore (SG); Muhandis SHIDDIQ, Singapore (SG)

(21) Appl. No.: 18/941,217

(22) Filed: Nov. 8, 2024

(51) Int. Cl. H01L 21/67; G01N 21/21; G01N 21/95; H01L 21/66; H01L 23/00

(52) U.S. Cl. CPC H10P 72/0616; G01N 21/211; G01N 21/9501; H10P 74/203; G01N 2021/213; H10W 80/301; H10W 80/312; H10W 80/327

(57) ABSTRACT

Methods and apparatus for processing a substrate are provided herein. For example, a method includes using an extended spectroscopic ellipsometer to direct a beam of electromagnetic radiation having a beam energy toward a portion of a substrate at an incident angle to produce an extended spectroscopic ellipsometry (ESE) data set from the portion of the substrate which includes a measured change of a phase and/or an amplitude of the beam of electromagnetic radiation reflecting away from the portion of the substrate relative to the beam of electromagnetic radiation directed toward the portion of the substrate. One or more properties of the portion of the substrate are then determined based at least in part on the ESE data set of the portion of the substrate.

### FIELD

Embodiments of the disclosure generally relate to methods and apparatuses for processing substrates. More particularly, embodiments of the disclosure relate to surface/interface characterization of a semiconductor substrate.

### BACKGROUND

Substrate (wafer) fabrication can include one or more processes. For example, substrate fabrication can include using one or more deposition processes (e.g., physical vapor deposition (PVD), chemical vapor deposition (CVD), atomic layer deposition (ALD), etc.), one or more bonding processes, one or more cleaning processes, one or more etch processes (e.g., wet etch, dry etch, etc.), and one or more polishing processes (e.g., chemical mechanical polishing (CMP) or other suitable polishing processes). Conventional methods and apparatus are configured for surface/interface characterization to detect properties of a surface of interest including the activation of the surface directed to the suitability of the surface for bonding to another surface. Such methods and apparatus of characterization require destruction of the surface and cannot be conducted in real time or used to monitor or control a process.

### SUMMARY

Methods and apparatus for processing a substrate are provided herein. In some embodiments, a method for processing a substrate includes directing a beam of electromagnetic radiation having a beam energy toward a portion of a substrate at an incident angle to produce an Extended Spectroscopic Ellipsometry (ESE) data set from the portion of the substrate comprising a measured change of a phase and/or an amplitude of the beam of electromagnetic radiation reflecting away from the portion of the substrate relative to the beam of electromagnetic radiation directed toward the portion of the substrate; and determining one or more properties of the portion of the substrate based at least in part on the ESE data set of the portion of the substrate; wherein the ESE data set for each portion of the substrate comprises a first data point obtained at a first incident angle and at a first beam energy, and at least one of: another data point of the same portion obtained at the first incident angle at a second beam energy which is different from the first beam energy, or another data point of the same portion obtained at a second incident angle at the first beam energy, wherein the second incident angle is different from the first incident angle.

In embodiments, an apparatus for processing a substrate comprises a processing platform for processing a substrate; and an extended spectroscopic ellipsometer (ESE) operably coupled to the processing platform and configured to direct a beam of electromagnetic radiation having a beam energy toward a portion of the substrate disposed on the processing platform at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate; and determine one or more properties of a surface of the portion of the substrate based at least in part on the ESE data set of the portion of the substrate; wherein the ESE data set for each portion of the substrate comprises a first data point obtained at a first incident angle and at a first beam energy, and at least one of: another data point of the same portion obtained at the first incident angle at a second beam energy which is different from the first beam energy, or another data point of the same portion obtained at a second incident angle at the first beam energy, wherein the second incident angle is different from the first incident angle. In embodiments, a non-transitory computer readable storage medium has stored thereon instructions that when executed by a processor perform a method for processing a substrate comprising directing a beam of electromagnetic radiation having a beam energy toward a portion of a substrate at an incident angle to produce an Extended Spectroscopic Ellipsometry (ESE) data set from the portion of the substrate comprising a measured change of a phase and/or an amplitude of the beam of electromagnetic radiation reflecting away from the portion of the substrate relative to the beam of electromagnetic radiation directed toward the portion of the substrate; and determining one or more properties of the portion of the substrate based at least in part on the ESE data set of the portion of the substrate; wherein the ESE data set for each portion of the substrate comprises a first data point obtained at a first incident angle and at a first beam energy, and at least one of: another data point of the same portion obtained at the first incident angle at a second beam energy which is different from the first beam energy, or another data point of the same portion obtained at a second incident angle at the first beam energy, wherein the second incident angle is different from the first incident angle.

Other and further embodiments of the present disclosure are described herein.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a block diagram of an apparatus in accordance with at least some embodiments of the present disclosure.

FIG. 2 is a platform or tool for processing a substrate in accordance with embodiments of the present disclosure.

FIG. 3 is a sequencing diagram in accordance with embodiments of the present disclosure.

FIG. 4 is a flowchart of a method of processing a substrate in accordance with embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods and an apparatus are provided herein. For example, methods and apparatus of the disclosure are directed to surface/interface characterization in semiconductor substrate processes. In embodiments, methods and apparatus described herein are configured to perform extended spectroscopic ellipsometry (ESE) in real-time during one or more substrate fabrication processes, directed to activation of the substrate for bonding, including hybrid bonding. Methods and apparatus according to embodiments disclosed herein provide real-time measurements characterizing surface/interface properties attributable to activation of the surface and suitability for bonding of the surface to another surface using simultaneously complex dielectric function and correlations as measured by ESE. The complex dielectric function can be used to probe various surface states relevant to bonding and hybrid bonding, as well as the state of subsurface layers of the substrate located at least 10 nm below the surface.

Characterization of an activation of a substrate for bonding, e.g., a bonding state may include a relative quantitative determination of a presence of various functional groups present on the surface of a dielectric portion of a substrate, and may also include the presence of various functional groups and/or a presence of a level of activation present on a metallic portion of the substrate via the presence of particular fingerprint peaks at a particular energy level determined from an ESE data set.

As the methods and apparatus described herein use ESE to monitor one or more surfaces of interest in real-time during one or more of the above-described substrate fabrication processes, as opposed to at the end of the substrate fabrication processes, destruction to the surfaces of interest is greatly reduced, if not eliminated.

In embodiments, a method of processing a substrate comprises directing a beam of electromagnetic radiation having a beam energy toward a portion of a substrate at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate; and determining one or more properties of the portion of the substrate based at least in part on the ESE data set of the portion of the substrate; wherein the ESE data set for each portion of the substrate comprises a first data point obtained at a first incident angle and at a first beam energy, and another data point of the same portion obtained at the first incident angle at a second beam energy which is different from the first beam energy, and/or another data point of the same portion obtained at a second incident angle at the first beam energy, wherein the second incident angle is different from the first incident angle.

In embodiments, the energy of the beam of electromagnetic radiation is from about 1 eV to about 600 eV, or from about 5 eV to about 600 eV, or from about 5 eV to about 200 eV. In embodiments, the energy of the beam of electromagnetic radiation is from about 5 eV to about 45 eV. In embodiments, the energy of the beam of electromagnetic radiation is from about 300 eV to about 600 eV.

In embodiments, the incident angle of the beam of electromagnetic radiation relative to the surface of the substrate is from about 0.5° to about 20°.

In embodiments, the one or more properties of the portion of the substrate comprise one or more properties of a surface of the portion of the substrate. In embodiments, the one or more properties of the portion of the substrate comprise one or more properties of a sub-surface layer of the portion of the substrate located at least 10 nm below a surface of the portion of the substrate.

In embodiments, the portion of the substrate comprises a metal in metallic form. In embodiments, the portion of the substrate comprises a dielectric.

In embodiments, the portion of the substrate comprises at least one of vias, trenches, or interconnects.

In embodiments, the directing of the beam of electromagnetic radiation having a beam energy toward the portion of the substrate at the incident angle to produce an ESE data set from the portion of the substrate is conducted in-situ, within a processing environment, before, during, or after a processing of the substrate without removing of the substrate from the processing environment.

In embodiments, the determining one or more properties of the portion of the substrate comprises determination of a bonding activation level of a surface of the portion of the substrate.

In embodiments, the method further comprises bonding and/or hybrid bonding of the substrate to another substrate.

In embodiments, the method further comprises subsequent processing of the substrate followed by repeating the directing of the beam of electromagnetic radiation having the beam energy toward the portion of a substrate at the incident angle to produce a second ESE data set from the portion of the substrate in essentially the same way as the ESE data set from the portion of the substrate was obtained; determining one or more properties of the portion of the substrate based at least in part on the second ESE data set of the portion of the substrate; and determining an effect of the subsequent processing on the one or more properties of the substrate based at least in part on the ESE data set of the portion of the substrate and the second ESE data set of the portion of the substrate.

In embodiments, the subsequent processing of the substrate comprises aging of substrate.

In embodiments, an apparatus for processing a substrate comprises a processing platform for processing a substrate; and an extended spectroscopic ellipsometer (ESE) operably coupled to the processing platform and configured to direct a beam of electromagnetic radiation having a beam energy toward a portion of the substrate disposed on the processing platform at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate; and determine one or more properties of a surface of the portion of the substrate based at least in part on the ESE data set of the portion of the substrate; wherein the ESE data set for each portion of the substrate comprises a first data point obtained at a first incident angle and at a first beam energy, and another data point of the same portion obtained at the first incident angle at a second beam energy which is different from the first beam energy, and/or another data point of the same portion obtained at a second incident angle at the first beam energy, wherein the second incident angle is different from the first incident angle.

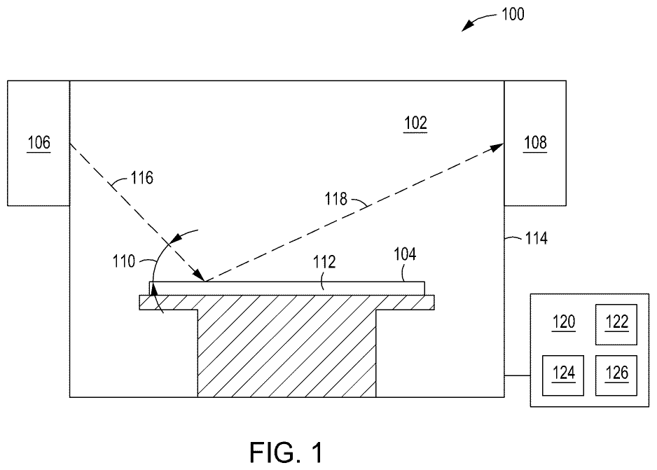

FIG. 1 is a block diagram of an apparatus 100 in accordance with at least some embodiments of the present disclosure comprising a processing chamber 114, comprising a processing platform 112 disposed within a processing environment 102 for processing a substrate 104. The apparatus 100 further includes an extended spectroscopic ellipsometer (ESE) 106 operably coupled to the processing platform 112 and configured to direct a beam of electromagnetic radiation 116 having a beam energy toward a portion of the substrate 104 disposed on the processing platform 112 at an incident angle 110 to produce an ESE data set from the portion of the substrate 104 comprising a measured change of a phase and/or an amplitude of the beam of electromagnetic radiation reflecting away, i.e., the reflected beam of electromagnetic radiation 118, from the portion of the substrate 104 relative to the beam of electromagnetic radiation 116 directed toward the portion of the substrate 104. In embodiments, a monochromatic, circularly polarized electromagnetic radiation source is employed, utilizing a polarizer and an adjustable retarder to produce the beam of electromagnetic radiation.

The ESE data set being determined from a suitable ESE detector 108, in communication with a data acquisition system 120 comprising a central processing unit 122, memory 124, and supporting circuitry 126. The data acquisition system 120 being configured to determine one or more properties of a surface of the portion of the substrate 104 based at least in part on the ESE data set of the portion of the substrate 104. The ESE data set for each portion of the substrate 104 comprising a first data point obtained at a first incident angle 110 and at a first beam energy of the beam of electromagnetic radiation 116.

In embodiments, the ESE data may further comprise at least one additional data point obtained from the same portion of the substrate 104 which is obtained at the same first incident angle 110 but at a different second beam energy of the beam of electromagnetic radiation 116. Accordingly, the ESE data set may include data obtained over a range of beam energies at the same incident angle.

In embodiments, the ESE data set may further comprise at least one additional data point obtained from the same portion of the substrate 104 which is obtained at the same beam energy, but at different incident angles, i.e., at a second incident angle at the first beam energy, wherein the second incident angle is different from the first incident angle. Accordingly, the ESE data set may include data obtained over a range of incident angles at the same beam energy.

In embodiments, the ESE data set may further comprise at least one additional data point obtained from the same portion of the substrate 104 which is obtained at a different beam energy and at a different incident angle. Accordingly, the ESE data set may include data obtained over a range of both incident angles and a range of beam energies.

The ESE data set may then be assembled and analyzed to determine one or more properties of a surface of the portion of the substrate, a subsurface layer of the portion of the substrate, or a combination thereof.

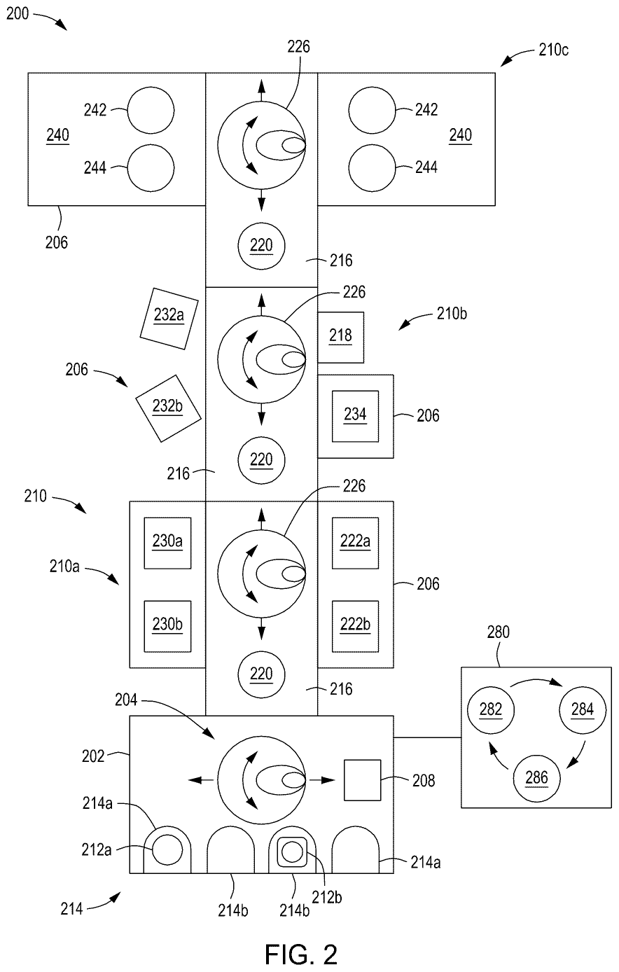

FIG. 2 depicts a schematic top view of a multi-chamber processing tool for bonding chiplets to a substrate in accordance with at least some embodiments of the present disclosure. The multi-chamber process tool 200 generally includes an equipment front end module (EFEM) 202 and a plurality of automation modules 210 that are serially coupled to the EFEM 202. The plurality of automation modules 210 are configured to shuttle one or more types of substrates 212 from the EFEM 202 through the multi-chamber process tool 200 and perform one or more processing steps to the one or more types of substrates 212. Each of the plurality of automation modules 210 generally include a transfer chamber 216 and one or more process chambers 206 coupled to the transfer chamber 216 to perform the one or more processing steps. The plurality of automation modules 210 are coupled to each other via their respective transfer chamber 216 to advantageously provide modular expandability and customization of the multi-chamber process tool 200. As depicted in FIG. 2, the plurality of automation modules 210 may include three automation modules, where a first automation module 210a is coupled to the EFEM 202, a second automation module 210b is coupled to the first automation module 210a, and a third automation module 210 c is coupled to the second automation module 210b.

The EFEM 202 includes a plurality of loadports 214 for receiving one or more types of substrates 212. In some embodiments, the one or more types of substrates 212 include 200 mm wafers, 300 mm wafers, 450 mm wafers, tape frame substrates, carrier substrates, silicon substrates, glass substrates, or the like. In some embodiments, the plurality of loadports 214 include at least one of one or more first loadports 214a for receiving a first type of substrate 212a or one or more second loadports 214b for receiving a second type of substrate 212b. In some embodiments, the first type of substrates 212a have a different size than the second type of substrates 212b. In some embodiments, the second type of substrates 212b include tape frame substrates or carrier substrates. In some embodiments, the second type of substrates 212b include a plurality of chiplets disposed on a tape frame or carrier plate. In some embodiments, the second type of substrates 212b may hold different types and sizes of chiplets. As such, the one or more second loadports 214b may have different sizes or receiving surfaces configured to load the second type of substrates 212b having different sizes.

In some embodiments, the EFEM 202 includes a scanning station 208 having substrate ID readers for scanning the one or more types of substrates 212 for identifying information.

An EFEM robot 204 is disposed in the EFEM 202 and configured to transport the first type of substrates 212a and the second type of substrates 212b between the plurality of loadports 214 to the scanning station 208. The EFEM robot 204 may rotate or rotate and move linearly.

The one or more process chambers 206 may be sealingly engaged with the transfer chamber 216. The transfer chamber 216 generally operates at atmospheric pressure but may be configured to operate at vacuum pressure. For example, the transfer chamber 216 may be a non-vacuum chamber configured to operate at an atmospheric pressure of about 700 Torr or greater. Additionally, while the one or more process chambers 206 are generally depicted as orthogonal to the transfer chamber 216, the one or more process chambers 206 may be disposed at an angle with respect to the transfer chamber 216 or a combination of orthogonal and at an angle. For example, the second automation module 210b depicts a pair of the one or more process chambers 206 disposed at an angle with respect to the transfer chamber 216.

The transfer chamber 216 includes a buffer 220 configured to hold one or more types of substrates 212. The transfer chamber 216 includes a transfer robot 226 configured to transfer the substrates 212 between the buffer 220, the one or more process chambers 206, and a buffer disposed in an adjacent automation module of the plurality of automation modules 210.

The one or more process chambers 206 may include atmospheric chambers that are configured to operate under atmospheric pressure and vacuum chambers that are configured to operate under vacuum pressure. Examples of the atmospheric chambers may generally include wet clean chambers, radiation chambers, heating chambers, metrology chambers, bonding chambers, or the like. Examples of vacuum chambers may include plasma chambers. The types of atmospheric chambers discussed above may also be configured to operate under vacuum, if needed. The one or more process chambers 206 may be any process chambers or modules needed to perform a bonding process, a dicing process, a cleaning process, a plating process, or the like.

The one or more process chambers 206 of each of the plurality of automation modules 210 may include at least one of a wet clean chamber 222, a plasma chamber 230, a degas chambers 232a and 232b, a radiation chamber 234, a bonder chamber 240 and the like.

The wet clean chambers 222a and 222b are configured to perform a wet clean process to clean the one or more types of substrates. The degas chamber 232 is configured to perform a degas process to remove moisture from the substrates 212. The plasma chamber 230a or 230b may be configured to perform an etch process to remove unwanted material, for example organic materials and oxides, from the first type of substrates 212. In some embodiments, the plasma chamber 230 may be configured to perform a deposition process, for example, a physical vapor deposition process, a chemical vapor deposition process, or the like. The radiation chambers 234 is configured to perform a radiation process on the substrate 212. The bonder chamber 240 generally includes a first support 242 to support the substrates 212 and a second support 244 to support another substrate 212.

In some embodiments, any of the plurality of automation modules 210 include a metrology chamber 218 configured to take measurements of the one or more types of substrates 212. In embodiments, the metrology chamber 218 may include an extended spectroscopic ellipsometer (ESE) operably coupled to the processing platform configured according to embodiments disclosed herein.

A controller 280 controls the operation of any of the multi-chamber processing tools described herein, including the multi-chamber processing tool 200. The controller 280 may use a direct control of the multi-chamber processing tool 200, or alternatively, by controlling the computers (or controllers) associated with the multi-chamber processing tool 200. In operation, the controller 280 enables data collection and feedback from the multi-chamber processing tool 200 to optimize performance of the multi-chamber processing tool 200. The controller 280 generally includes a central processing unit (CPU) 282, a memory 284, and a support circuit 286. The CPU 282 may be any form of a general-purpose computer processor that can be used in an industrial setting. The support circuit 286 is conventionally coupled to the CPU 282 and may comprise a cache, clock circuits, input/output subsystems, power supplies, and the like. Software routines, such as a method as described below may be stored in the memory 284 and, when executed by the CPU 282, transform the CPU 282 into a specific purpose computer (controller 280). The software routines may also be stored and/or executed by a second controller (not shown) that is located remotely from the multi-chamber processing tool 200. In embodiments, the controller 280 is further configured to function as the data acquisition system of the extended spectroscopic ellipsometer.

The memory 284 is in the form of computer-readable storage media that contains instructions, when executed by the CPU 282, to facilitate the operation of the semiconductor processes and equipment. The instructions in the memory 284 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

In embodiments, an extended spectroscopic ellipsometer is operably coupled to one or more of the processing chambers and/or the metrology chambers of the platform tool. In embodiments, all processes described herein may be performed in the multi-chamber processing tool. In some embodiments, some processes may be performed in the multi-chamber processing tool and others performed in a stand-alone tool.

In embodiments, ESE is utilized to characterize surface/interface properties or characteristics on one or more surfaces of a substrate utilizing a complex dielectric function to produce a plurality of ESE data sets. The surface states can be directly correlated to downstream reliability performance, such as bonding strength, thus offering a significant advantage from device performance and yield standpoint, e.g., performance and yield can be identified early before completion of a device the substrate, as opposed to the conventional methods of testing performance and yield after assembly (packaging).

In embodiments, the data acquisition system of the ESE, also referred to as a controller, uses ellipsometry raw data (e.g., ψ (amplitude) and Δ (phase)) to extract dielectric function (e.g., ε1 and ε2) of material according to equations (1)-(3):

$$ρ ≡ tan Ψexp ( i Δ ) ≡ {r}_{p} / {r}_{s} \qquad ( 1 )$$

$${ε}_{1} = {n}^{2} - {k}^{2} \qquad ( 2 )$$

$${ε}_{2} = 2 nk \qquad ( 3 )$$

With respect to hybrid bonding, the dielectric surface property (ρ) can be a critical metric to achieve high bonding strength. In ellipsometry, the ratio in amplitude (ψ) and phase difference (Δ) are directly related to the complex dielectric function (ε=ε₁+iε₂). The direct relationship is apparent in equation (1), where the two ellipsometric parameters (ψ, Δ) are equivalent to the ratio between the p-polarized (rₚ) and s-polarized reflectance (rₛ). The reflectance is dependent on the material's refractive index (n) and extinction coefficient (k), where the relation between these two parameters and the complex dielectric function is shown in equation (2) and equation (3).

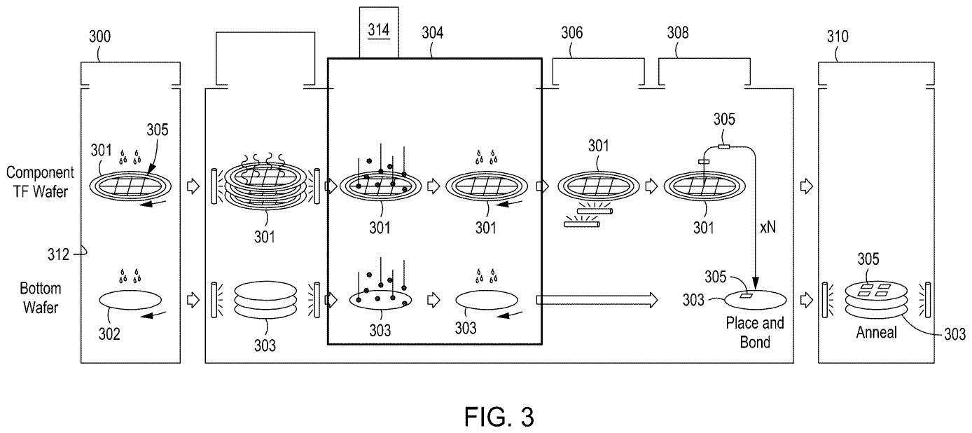

FIG. 3 depicts is a sequencing diagram of the method 300 according to embodiments disclosed herein. Initially, one or more substrates such as a top substrate 301 and a bottom substrate 303 can be loaded into a platform tool or other processing chamber. The top substrate 301 and the bottom substrate 303 can be made from one or more metals, e.g., Cu embedded in one or more dielectric materials, e.g., silicon carbon nitride (SiCN), silicon oxide (SiO₂), and/or the like. One or more dies 305 (e.g., a plurality of die 305) can be disposed on a top surface of the top substrate 301.

Any number of processes can be performed on the top substrate 301 and/or the bottom substrate 303. For example, in embodiments, the top substrate 301 and the bottom substrate 303 may undergo cleaning in a cleaning chamber 312, degassing in a degassing chamber 302, undergo one or more plasma and/or deposition processes in a plasma processing chamber 304, one or more curing or irradiating or UV processes in an irradiation chamber 306, followed by a flipping of the chiplet or die and bonding of the portion of the top substrate 301 to the bottom substrate 303 in a bonding chamber 308. The processed substrate may then be annealed in an annealing chamber 310.

At any one of the various processes, and any one of the various processing chambers may be coupled to an extended spectroscopic ellipsometer 314 configured to direct a beam of electromagnetic radiation having a beam energy toward a portion of the substrate at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate; and determine one or more properties of the portion of the substrate based at least in part on the ESE data set of the portion of the substrate according to embodiments disclosed herein.

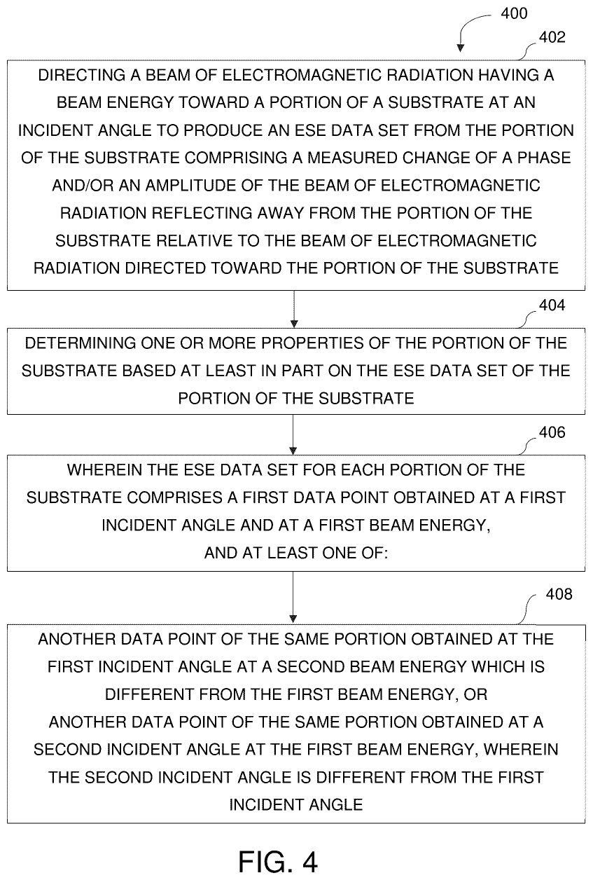

FIG. 4 depicts a flowchart of a method of processing a substrate 400 according to embodiments disclosed herein. The method comprises directing a beam of electromagnetic radiation having a beam energy toward a portion of a substrate at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate (block 402); and determining one or more properties of the portion of the substrate based at least in part on the ESE data set of the portion of the substrate (block 404), wherein the ESE data set for each portion of the substrate comprises a first data point obtained at a first incident angle and at a first beam energy (block 406), and at least one of: another data point of the same portion obtained at the first incident angle at a second beam energy which is different from the first beam energy, or another data point of the same portion obtained at a second incident angle at the first beam energy, wherein the second incident angle is different from the first incident angle (block 408).

The ESE data set from the portion of the substrate comprises a measured change of a phase (Δ) and an amplitude (ψ) of the beam of electromagnetic radiation reflecting away from the portion of the substrate relative to the beam of electromagnetic radiation directed toward the portion of the substrate. In embodiments, the extended spectroscopic ellipsometer can direct the beam at one or more suitable angles to detect a particular surface state. In embodiments, the beam of electromagnetic energy is directed at an angle of incidence (incident angle) relative to the top surface of the top substrate from about 0.5° to about 80°, or from about 0.5° to about 50°, or from about 0.5° to about 40°. The energy of the beam can be from about 5 eV to about 600 eV, depending on the species being determined. In embodiments, when a metal surface is being characterized, the energy of the beam may be from about 5 eV to about 45 eV, or about 300 eV to about 600 eV, or from about 400 eV to about 600 eV. In such embodiments, the incident angle may be from about 1° to about 50°, or from about 0.5° to about 20°.

In other embodiments, when a dielectric surface is being characterized, e.g., SiCN, the energy of the beam may be from about 5 eV to about 200 eV, or from about 20 eV to about 100 eV, or from about 390 eV to about 450 eV, or from about 390 eV to about 430 eV, or from about 520 eV to about 570 eV, or from about 525 eV to about 560 eV, and the incident angle may be from about 1° to about 50°, or from about 0.5° to about 20°.

The determining one or more properties of the portion of the substrate based at least in part on the ESE data set of the portion of the substrate comprises correlating the ESE data set with one or more parameters of the surface of the substrate using the complex dielectric function obtained from the change of the phase (A) and amplitude (Y′) of the reflected beam to determine the presence of one or more species, and/or a state of level of activation of the surface of the substate. Various correlations may be used to obtain important information about surface, interface, and/or defects, each of which have rich physical properties. For example, for the same dielectric under different surface treatment, electronic correlations are different and yield a unique spectrum of complex dielectric function which can be readily correlated to downstream bonding performance. For instance, the imaginary part of the complex dielectric function, ε₂, is proportional to the optical absorption and optical conductivity of the material, while the real part of the complex dielectric function, ε₁, is proportional to the electron correlations of the material. Change in the complex dielectric function, where the real and imaginary part are dependent on each other, may reflect differences in fabrication conditions and/or material performance.

Accordingly, the methods disclosed herein may be utilized to improve bonding yield without having to conduct pre-bonding vs. post-bonding inspection, thereby increasing throughput as post-bonding inspection is no longer mandatory. The methods disclosed herein may be utilized to guarantee high bonding strength without the need for post-bonding die shear testing, thereby further improving yields. The methods disclosed herein are non-destructive and may be performed in-situ within the processing chamber. The are applicable to both metal and dielectric substrates, the methods allow surface and sub-surface characterization, providing comprehensive metric for hybrid bonding, and allow for real-time monitoring for semiconductor process control and/or on-board metrology applications.

In embodiments, one or more of the processes are controlled based at least in part on the determined states of the substrate, which in embodiments are correlated to downstream bonding performance.

In embodiments, the one or more properties of the portion of the substrate based at least in part on the ESE data set of the portion of the substrate can be utilized to control a bonding process including a hybrid bonding process.

Likewise, ESE data set of the portion of the substrate can be utilized to control any of the processes prior to and/or subsequent to bonding. For example, the ESE data set can be used as described herein during a cleaning process, a degas process, the bonding process, an ultraviolet process, an annealing process, and/or the like.

### EMBODIMENTS

### Embodiments Disclosed Herein Include:

E1. A method of processing a substrate, comprising:
directing a beam of electromagnetic radiation having a beam energy toward a portion of a substrate at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate; and
determining one or more properties of the portion of the substrate based at least in part on the ESE data set of the portion of the substrate;
wherein the ESE data set for each portion of the substrate comprises a first data point obtained at a first incident angle and at a first beam energy, and at least one of:
   another data point of the same portion obtained at the first incident angle at a second beam energy which is different from the first beam energy, or
   another data point of the same portion obtained at a second incident angle at the first beam energy, wherein the second incident angle is different from the first incident angle.
E2. The method according to embodiment E1, wherein the energy of the beam of electromagnetic radiation is from about 5 eV to about 600 eV.
E3. The method according to embodiments E1-E2, wherein the energy of the beam of electromagnetic radiation is from about 5 eV to about 200 eV.
E4. The method according to embodiments E1-E3, wherein the energy of the beam of electromagnetic radiation is from about 5 eV to about 45 eV.
E5. The method according to embodiments E1-E4, wherein the energy of the beam of electromagnetic radiation is from about 300 eV to about 600 eV.
E6. The method according to embodiments E1-E5, wherein the incident angle is from about 0.5° to about 50°.
E7. The method according to embodiments E1-E6, wherein the incident angle is from about 0.5° to about 20°.
E8. The method according to embodiments E1-E7, wherein the one or more properties of the portion of the substrate comprise one or more properties of a surface of the portion of the substrate.
E9. The method according to embodiments E1-E8, wherein the one or more properties of the portion of the substrate comprise one or more properties of a sub-surface layer of the portion of the substrate located at least 10 nm below a surface of the portion of the substrate.
E10. The method according to embodiments E1-E9, wherein the portion of the substrate comprises a metal in metallic form.
E11. The method according to embodiments E1-E10, wherein the portion of the substrate comprises a dielectric.
E12. The method according to embodiments E1-E11, wherein the portion of the substrate comprises at least one of vias, trenches, or interconnects.
E13. The method according to embodiments E1-E12, wherein the directing the beam of electromagnetic radiation having a beam energy toward the portion of the substrate at the incident angle to produce an ESE data set from the portion of the substrate is conducted in-situ, within a processing environment, before, during, or after a processing of the substrate without removing of the substrate from the processing environment.
E14. The method according to embodiment E13, further comprising bonding and/or hybrid bonding of the substrate to another substrate.
E15. The method according to embodiments E1-E14, wherein the determining one or more properties of the portion of the substrate comprises determination of a bonding activation level of a surface of the portion of the substrate.
E16. The method according to embodiments E1-E15, further comprising:
subsequent processing of the substrate followed by repeating the directing of the beam of electromagnetic radiation having the beam energy toward the portion of a substrate at the incident angle to produce a second ESE data set from the portion of the substrate in essentially the same way as the ESE data set from the portion of the substrate was obtained;
determining one or more properties of the portion of the substrate based at least in part on the second ESE data set of the portion of the substrate; and
determining an effect of the subsequent processing on the one or more properties of the substrate based at least in part on the ESE data set of the portion of the substrate and the second ESE data set of the portion of the substrate.
E17. The method according to embodiments E1-E16, wherein the subsequent processing of the substrate comprises aging of substrate.
E18. An apparatus for processing a substrate, comprising:
a processing platform for processing a substrate; and
an extended spectroscopic ellipsometer (ESE) operably coupled to the processing platform and configured to:
   direct a beam of electromagnetic radiation having a beam energy toward a portion of the substrate disposed on the processing platform at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate; and
   determine one or more properties of a surface of the portion of the substrate based at least in part on the ESE data set of the portion of the substrate;
   wherein the ESE data set for each portion of the substrate comprises a first data point obtained at a first incident angle and at a first beam energy, and at least one of:
      another data point of the same portion obtained at the first incident angle at a second beam energy which is different from the first beam energy, or
      another data point of the same portion obtained at a second incident angle at the first beam energy, wherein the second incident angle is different from the first incident angle.
E19. The apparatus according to embodiment E18, wherein the beam energy is from about 5 eV to about 600 eV.

The apparatus according to embodiments E18-E19, wherein the incident angle is from about 0.5° to about 50°.

While the foregoing is directed to embodiments of the present disclosure, other and further embodiments of the disclosure may be devised without departing from the basic scope thereof.

1. A method of processing a substrate, comprising:
directing a beam of electromagnetic radiation having a beam energy toward a portion of a substrate at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate; and
determining one or more properties of the portion of the substrate based at least in part on the ESE data set of the portion of the substrate;
wherein the ESE data set for each portion of the substrate comprises a first data point obtained at a first incident angle and at a first beam energy, and at least one of:
another data point of the same portion obtained at the first incident angle at a second beam energy which is different from the first beam energy, or
another data point of the same portion obtained at a second incident angle at the first beam energy, wherein the second incident angle is different from the first incident angle.

2. The method of claim 1, wherein the energy of the beam of electromagnetic radiation is from about 5 eV to about 600 eV.

3. The method of claim 1, wherein the energy of the beam of electromagnetic radiation is from about 5 eV to about 200 eV.

4. The method of claim 1, wherein the energy of the beam of electromagnetic radiation is from about 5 eV to about 45 eV.

5. The method of claim 1, wherein the energy of the beam of electromagnetic radiation is from about 300 eV to about 600 eV.

6. The method of claim 1, wherein the incident angle is from about 0.5° to about 50°.

7. The method of claim 1, wherein the incident angle is from about 0.5° to about 20°.

8. The method of claim 1, wherein the one or more properties of the portion of the substrate comprise one or more properties of a surface of the portion of the substrate.

9. The method of claim 1, wherein the one or more properties of the portion of the substrate comprise one or more properties of a sub-surface layer of the portion of the substrate located at least 10 nm below a surface of the portion of the substrate.

10. The method of claim 1, wherein the portion of the substrate comprises a metal in metallic form.

11. The method of claim 1, wherein the portion of the substrate comprises a dielectric.

12. The method of claim 1, wherein the portion of the substrate comprises at least one of vias, trenches, or interconnects.

13. The method of claim 1, wherein the directing the beam of electromagnetic radiation having a beam energy toward the portion of the substrate at the incident angle to produce an ESE data set from the portion of the substrate is conducted in-situ, within a processing environment, before, during, or after a processing of the substrate without removing of the substrate from the processing environment.

14. The method of claim 13, further comprising bonding and/or hybrid bonding of the substrate to another substrate.

15. The method of claim 1, wherein the determining one or more properties of the portion of the substrate comprises determination of a bonding activation level of a surface of the portion of the substrate.

16. The method of claim 1, further comprising:
subsequent processing of the substrate followed by repeating the directing of the beam of electromagnetic radiation having the beam energy toward the portion of a substrate at the incident angle to produce a second ESE data set from the portion of the substrate in essentially the same way as the ESE data set from the portion of the substrate was obtained;
determining one or more properties of the portion of the substrate based at least in part on the second ESE data set of the portion of the substrate; and
determining an effect of the subsequent processing on the one or more properties of the substrate based at least in part on the ESE data set of the portion of the substrate and the second ESE data set of the portion of the substrate.

17. The method of claim 1, wherein the subsequent processing of the substrate comprises aging of substrate.

18. An apparatus for processing a substrate comprising:
a processing platform for processing a substrate; and
an extended spectroscopic ellipsometer (ESE) operably coupled to the processing platform and configured to:
direct a beam of electromagnetic radiation having a beam energy toward a portion of the substrate disposed on the processing platform at an incident angle to produce an ESE data set from the portion of the substrate comprising a measured change of a phase and/or an amplitude of the beam of electromagnetic radiation reflecting away from the portion of the substrate relative to the beam of electromagnetic radiation directed toward the portion of the substrate; and
determine one or more properties of a surface of the portion of the substrate based at least in part on the ESE data set of the portion of the substrate;
wherein the ESE data set for each portion of the substrate comprises a first data point obtained at a first incident angle and at a first beam energy, and at least one of:
another data point of the same portion obtained at the first incident angle at a second beam energy which is different from the first beam energy, or
another data point of the same portion obtained at a second incident angle at the first beam energy, wherein the second incident angle is different from the first incident angle.

19. The apparatus of claim 18, wherein the beam energy is from about 5 eV to about 600 eV.
The apparatus of claim 18, wherein the incident angle is from about 0.5° to about 50°.
